(19) United States
(12) Patent Application Publication
(10) Pub. No.: US 2025/0226808 A1
(43) Pub. Date: Jul. 10, 2025

(54) METHOD OF MANUFACTURING PIEZOELECTRIC SUBSTRATE FOR SAW RESONATOR WITH IMPROVED CHARACTERISTIC AND PIEZOELECTRIC SUBSTRATE MANUFACTURED USING THE SAME

(71) Applicant: WISOL CO., LTD., Osan-si (KR)

(72) Inventors: Tae Hyun KIM, Osan-si (KR); Yoshikazu KIHARA, Osan-si (KR)

(73) Assignee: WISOL CO., LTD., Osan-si (KR)

(21) Appl. No.: 18/989,741

(22) Filed: Dec. 20, 2024

(30) Foreign Application Priority Data
Jan. 4, 2024 (KR) 10-2024-0001709

(51) Int. Cl. H03H 3/08; H03H 9/02; H03H 9/25

(52) U.S. Cl. CPC H03H 3/08; H03H 9/02559; H03H 9/02574; H03H 9/25

(57) ABSTRACT

Provided is a method of manufacturing a piezoelectric substrate for SAW resonators with improved resonance characteristics and a piezoelectric substrate for SAW resonators manufactured by this method. The manufacturing method of a piezoelectric substrate for a SAW resonator includes preparing a laminated substrate, and heat-treating the laminated substrate to reduce the gas contained in at least one layer of the laminated substrate.

### BACKGROUND OF THE INVENTION

### Field of the Invention

The present invention relates to a method of manufacturing a piezoelectric substrate for a SAW resonator with improved resonance characteristics and a piezoelectric substrate for a SAW resonator manufactured through the method.

### Background of the Related Art

Surface Acoustic Waves (SAW) refer to waves that propagate along the surface of an elastic solid. These elastic surface waves concentrate energy near the surface as they propagate and are classified as mechanical waves. Surface Acoustic Wave devices are electromechanical devices that utilize the interaction between these surface acoustic waves and semiconductor conduction electrons, using surface acoustic waves transmitted to the surface of a piezoelectric crystal. These devices can have a wide range of industrial applications, such as sensors, oscillators, and filters, and offer various advantages, including miniaturization, lightweight, robustness, stability, sensitivity, low cost, and real-time performance.

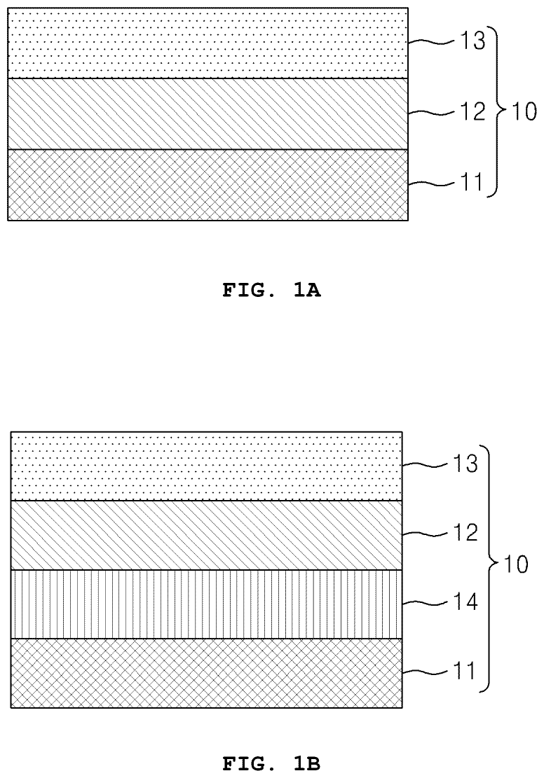

A piezoelectric substrate on which a plurality of interdigital (IDT) electrodes are formed may have a four-layer structure in which a high-speed layer 14, a low-speed layer 12, and a piezoelectric layer 13 are sequentially stacked on the support substrate 11 as shown in FIG. 1A, or a three-layer structure of a support substrate 11, a low-speed layer 12, and a piezoelectric layer 13 as shown in FIG. 1B. Here, the high-speed layer or the low-speed layer refers to a layer that transmits a high-speed or low-speed sound speed based on an elastic wave propagated by the piezoelectric layer 13 of the LT/LN substrate.

Various attempts have been made to improve the characteristics represented by Q factors in such SAW resonators, and the introduction of technical means to reduce defects and improve quality is continuously required during the manufacturing process of piezoelectric substrates such as FIGS. 1A and 1B.

The technical problem to be solved by the present invention is to provide a method of manufacturing a piezoelectric substrate for a SAW resonator, in which an unnecessary gas content is reduced and resonance characteristics are improved, and a piezoelectric substrate for a SAW resonator manufactured thereby.

The technical problems of the present invention are not limited to those mentioned above, and other technical problems that are not mentioned will be clearly understood by those skilled in the art from the description below.

A method of manufacturing a piezoelectric substrate for a Surface Acoustic Wave (SAW) resonator according to some embodiments of the present invention to solve the above technical problems includes preparing a laminated substrate, and reducing the gas contained in at least one layer of the laminated substrate by heat-treating the laminated substrate.

In some embodiments of the present invention, the laminated substrate may include a low-sonic layer (layer of low sound velocity).

In some embodiments of the present invention, the laminated substrate may further include a support substrate formed on one surface of the low-sonic layer.

In some embodiments of the present invention, the laminated substrate may further include a high-sonic layer (layer of high sound velocity) formed between the support substrate and the low-speed layer.

In some embodiments of the present invention, the step of bonding a piezoelectric layer to an upper surface of the low-sonic layer may be further included.

In some embodiments of the present invention, the laminated substrate may further include a piezoelectric layer formed on one surface of the low-sonic layer.

In some embodiments of the present invention, the piezoelectric layer may have a thickness of 200 nm to 1 μm.

In some embodiments of the present invention, a step of bonding the heat-treated laminated substrate and the silicon support substrate may be further included.

In some embodiments of the present invention, the step of bonding the heat-treated laminated substrate and the silicon support substrate may include bonding the other surface of the heat-treated low-sonic layer and one surface of the high-sonic layer formed on one surface of the silicon support substrate.

In some embodiments of the present invention, the laminated substrate may further include a silicon support substrate formed on the other surface of the low-sonic layer.

In some embodiments of the present invention, the step of reducing the gas included in at least one layer of the laminated substrate by heat-treating the laminated substrate may include the step of reducing the first gas under the first temperature condition, and the step of reducing the second gas under the second temperature condition higher than the first temperature condition.

In some embodiments of the present invention, the first gas may include oxygen (O2) or H2O, and the second gas may include at least one of oxygen, H2O, and argon (Ar).

In some embodiments of the present invention, the first temperature may be 200 to 350° C., and the second temperature may be 400 to 600° C.

In some embodiments of the present invention, the step of reducing gas included in at least one layer in the laminated structure by heat-treating the piezoelectric substrate may include a step of performing heat treatment while increasing the temperature in the heat treatment chamber from the first temperature to the second temperature.

The piezoelectric substrate for a SAW resonator according to some embodiments of the present invention for solving the technical problem is manufactured by the method described above.

Specific matters of the embodiments are included in the detailed description and drawings.

According to embodiments of the present invention, a method of manufacturing a piezoelectric substrate for a SAW resonator and a piezoelectric substrate for a SAW resonator manufactured through the method can be outgassed from impurities such as oxygen and argon gas contained in the laminated substrate by heating the laminated substrate.

Crystallinity and internal defects of the low-sonic layer and the high-sonic layer may be improved by the emission of such a gas. Also, bonding strength between the low-sonic layer and the piezoelectric layer may be improved by the heat treatment.

Meanwhile, there is a problem that cracks may occur during the heat treatment process as each layer of the laminated substrate has different thermal expansion coefficients. In the method of manufacturing a piezoelectric substrate for a SAW resonator of the present invention, a piezoelectric layer of 1 μm or less can be used to reduce thermal stress applied to the laminated substrate, thereby reducing cracks occurring on the laminated substrate during heat treatment.

The effects of the present invention are not limited to the above-mentioned effects, and other effects not mentioned will be clearly understood by those skilled in the art from the description of the invention and the claims.

FIGS. 1A and 1B are for explaining a piezoelectric substrate for a SAW resonator according to the prior art.

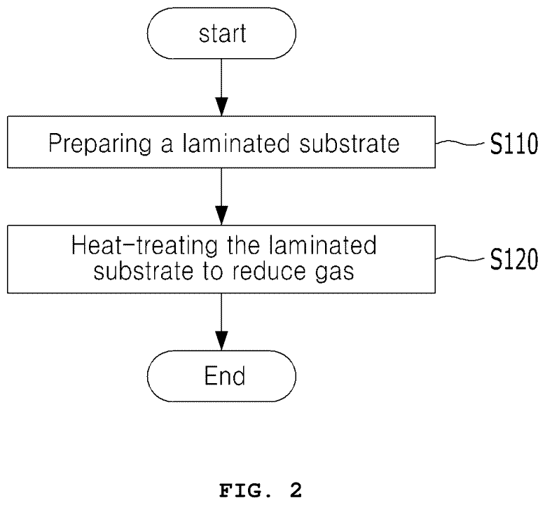

FIG. 2 is a flowchart illustrating a method of manufacturing a piezoelectric substrate for a SAW resonator according to an embodiment of the present invention.

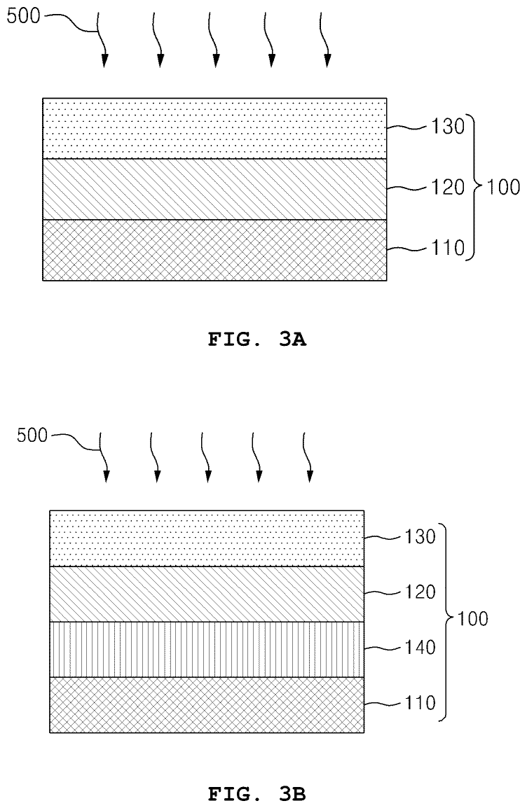

FIGS. 3A and 3B are intermediate step diagrams for describing a method of manufacturing a piezoelectric substrate for a SAW resonator according to an embodiment of the present invention.

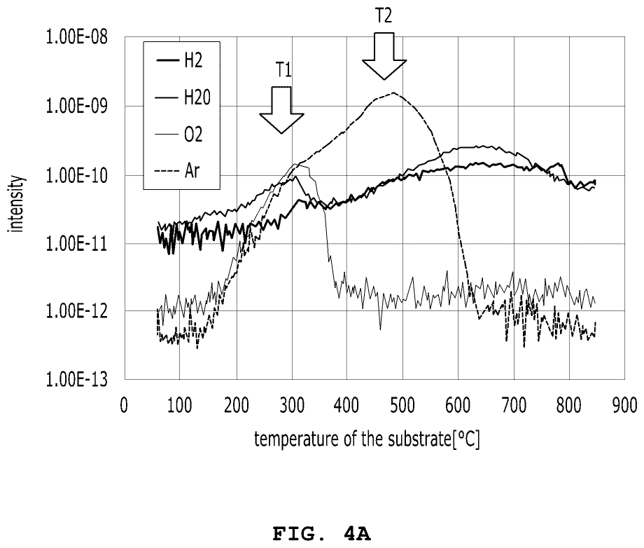

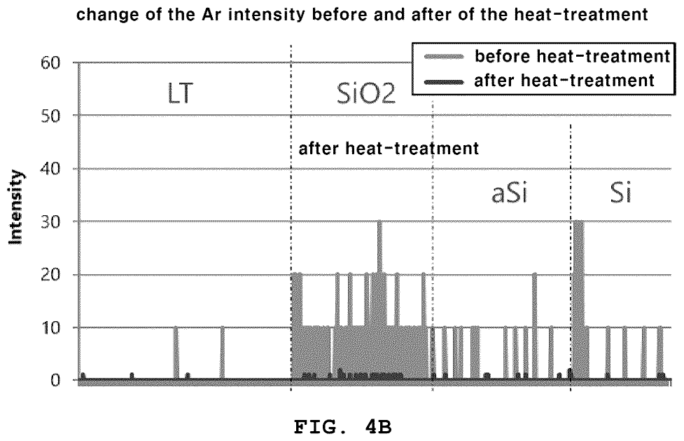

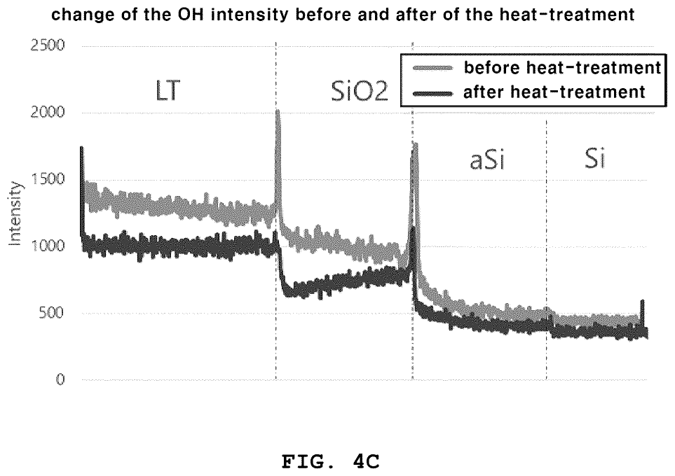

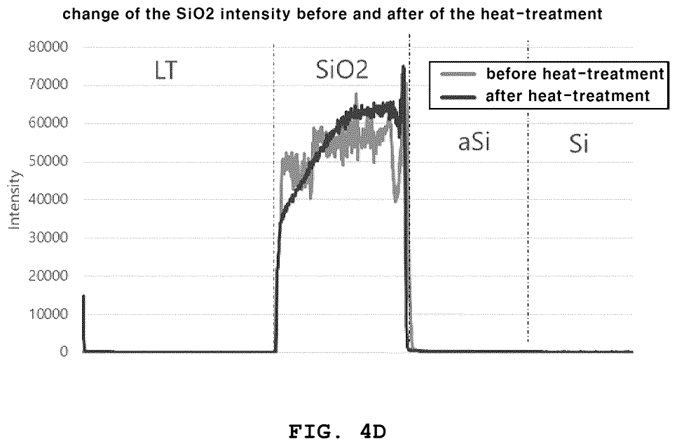

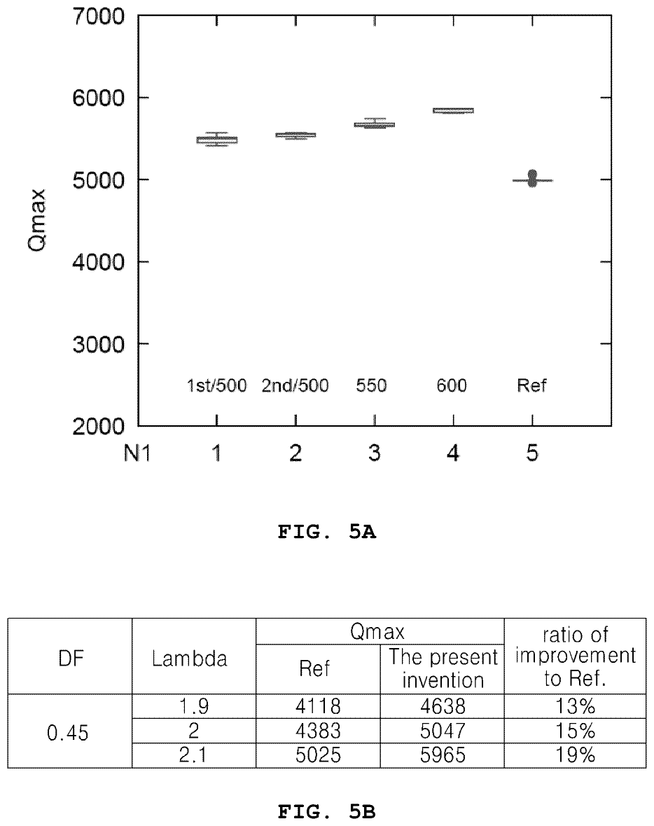

FIGS. 4A to 5B are for explaining effects that may be obtained by the method of manufacturing a piezoelectric substrate for a SAW resonator according to an embodiment of the present invention.

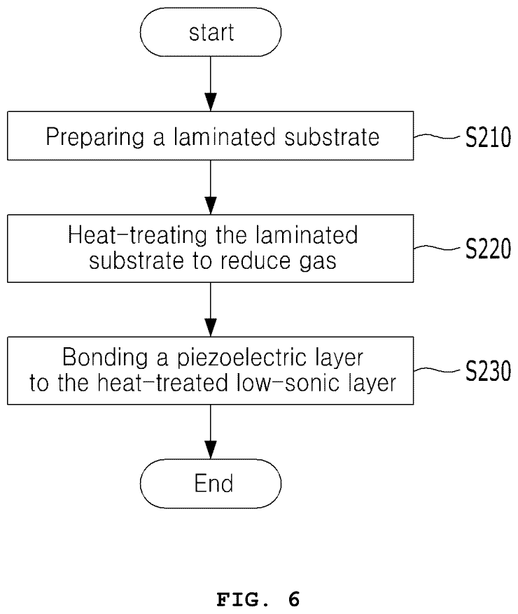

FIG. 6 is a flowchart illustrating a method of manufacturing a piezoelectric substrate for a SAW resonator according to another embodiment of the present invention.

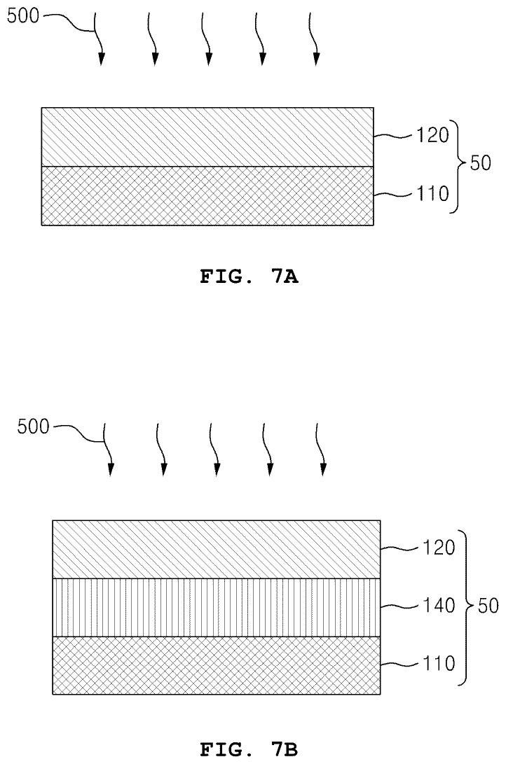

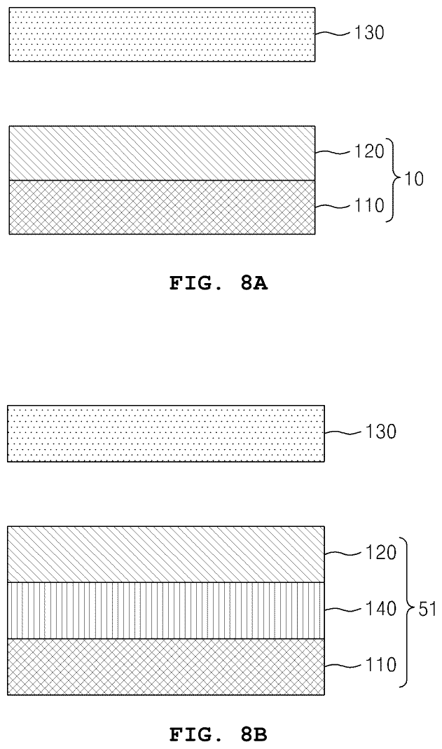

FIGS. 7A to 8B are intermediate step diagrams for describing a method of manufacturing a piezoelectric substrate for a SAW resonator according to another embodiment of the present invention.

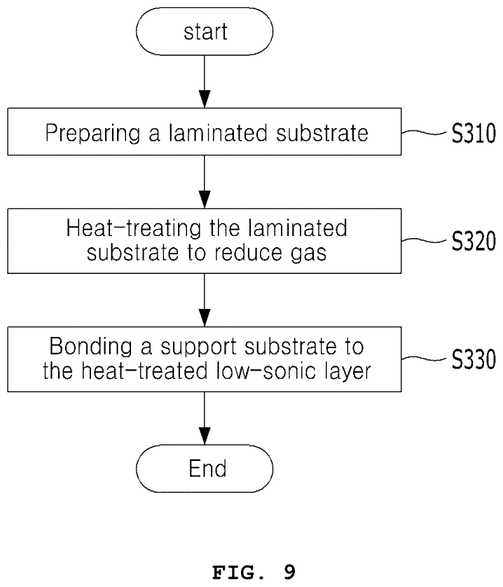

FIG. 9 is a flowchart illustrating a method of manufacturing a piezoelectric substrate for a SAW resonator according to another embodiment of the present invention.

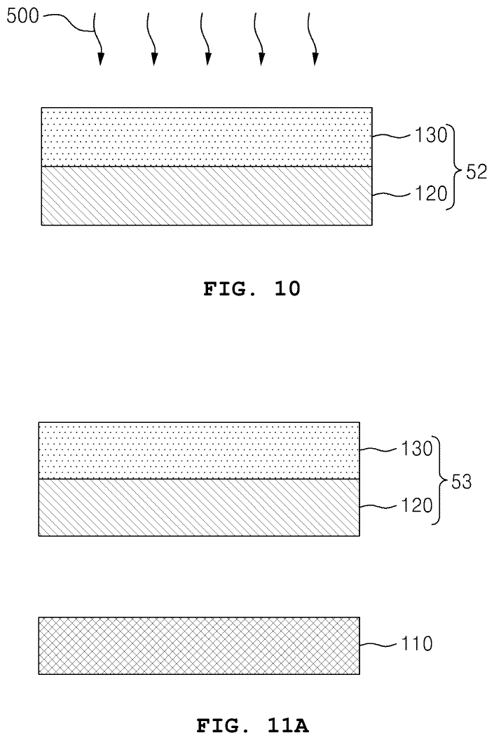

FIGS. 10 to 11B are intermediate step diagrams of a method of manufacturing a piezoelectric substrate for a SAW resonator according to another embodiment of the present invention.

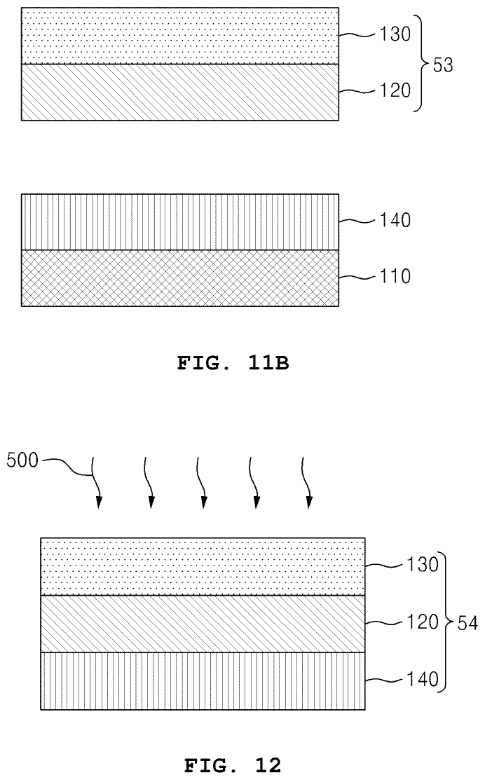

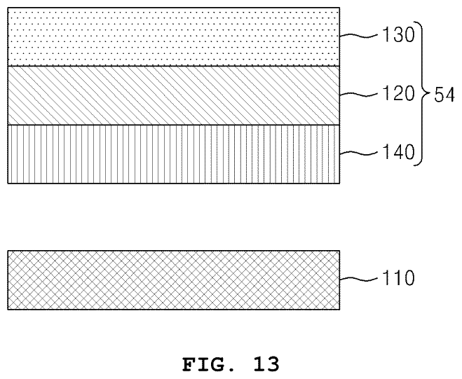

FIGS. 12 and 13 are intermediate step diagrams of a method of manufacturing a piezoelectric substrate for a SAW resonator according to another embodiment of the present invention.

The advantages and features of the present invention and the method for achieving them will become clear by referring to the embodiments described below in detail together with the accompanying drawings. However, the present invention is not limited to the embodiments disclosed below and will be implemented in various different forms. These embodiments are provided only to make the disclosure of the present invention complete and to fully inform those skilled in the art of the scope of the present invention, and the present invention is only defined by the scope of the claims. Like reference numerals refer to like elements throughout the specification.

“And/or” includes each of the mentioned items and all combinations of one or more of the mentioned items.

The terms used in this specification are to describe the embodiments and are not to limit the present invention. In this specification, singular forms also include plural forms unless specially stated otherwise in the phrases. The terms “comprises” and/or “comprising” used in this specification means that the mentioned components, steps, operations, and/or elements do not exclude the presence or addition of one or more other components, steps, operations and/or elements.

In addition, throughout the specification, when a part is said to be “connected” to another part, this also includes “indirectly” or “electrically connected” cases with intervention of other members or components therebetween, as well as “directly connected” cases.

In addition, throughout the specification, the description that each layer (film), region, pattern, or structure is formed “above/on” or “beneath/under” a substrate, each layer (film), region, pad, or pattern includes both cases that they are formed directly and formed with intervention of other layers. The criteria for being above/on or beneath/under each layer are explained with reference to the drawings.

In addition, expressions such as ‘first, second’, and the like are only used to distinguish a plurality of components, and do not limit the sequence of the components or other features.

Unless defined otherwise, all the terms (including technical and scientific terms) used in this specification may be used as meanings that can be commonly understood by those skilled in the art. In addition, terms defined in commonly used dictionaries are not interpreted ideally or excessively unless clearly and specifically defined.

The present invention will be described in detail with reference to the drawings.

FIG. 2 is a flowchart illustrating a method of manufacturing a piezoelectric substrate for a SAW resonator according to an embodiment of the present invention.

Referring to FIG. 2, a method of manufacturing a piezoelectric substrate for a SAW resonator according to an embodiment of the present invention includes a step S110 of preparing a laminated substrate and a step S120 of heat-treating the laminated substrate to reduce gas. Hereinafter, a manufacturing method of the present invention will be described in more detail with reference to FIG. 3A and the like.

FIGS. 3A and 3B are intermediate step diagrams illustrating a method of manufacturing a piezoelectric substrate for a SAW resonator according to an embodiment of the present invention.

Referring to FIG. 3A, a process of preparing a laminated substrate 100 including a support substrate 110, a low-sonic layer 120, and a piezoelectric layer 130 and heat-treating the laminated substrate 100 is illustrated.

The support substrate 110 may include, for example, a silicon substrate, a sapphire substrate, a silicon carbide (SiC) substrate, a quartz substrate, and the like.

The low-sonic layer 120 is a layer having a transverse sound wave speed lower than that of the piezoelectric layer 130, and may include, for example, silicon oxide (SiO2). The low-sonic layer 120 may be formed, for example, by forming silicon oxide in a sputter, chemical vapor deposition (CVD), or thermal oxidation device. The thickness of the low-sonic layer 120 may be 200 nm to 800 nm.

In some embodiments of the present invention, the low-sonic layer 120 may be composed of two or more layers configured to have different transverse sound wave speeds while being lower than the piezoelectric layer 130.

The piezoelectric layer 130 includes a piezoelectric element and may generate an acoustic wave from a signal applied to a plurality of IDT electrodes formed thereon. The piezoelectric layer may include, for example, a material such as LiTaO3(LT), LiNbO3(LN), etc. The piezoelectric layer 130 may be bonded to one surface of the low-sonic layer 120 via a bonding surface formed by polishing one surface of a single crystal LT or LN substrate. According to an embodiment, silicon oxide may be formed on the piezoelectric layer 130 and bonded to the low-sonic layer 120 to improve bonding strength.

The thickness of the piezoelectric layer 130 may be determined by a wavelength 2 defined by the pitch of the IDT electrodes formed on the piezoelectric layer 130, and may be, for example, 200 nm to 2 μm, preferably 1 μm or less.

Meanwhile, as shown in FIG. 3B, the laminated substrate 100 may include a high-sonic layer 140 between the support substrate 110 and the low-sonic layer 120. The high-sonic layer 140 may be formed of amorphous silicon (a-Si), polysilicon (PolySi), silicon nitride (SiN), silicon oxynitride (SiON), aluminum nitride (AlN), boron nitride (BN), diamond, or the like. The high-sonic layer 140 is a layer that transmits a faster sound speed than an acoustic wave propagating through the piezoelectric layer 130, and may be bonded to the support substrate 110 by plasma activation bonding, hydrophilic bonding, or the like. The high-sonic layer 140 may have a thickness of, for example, 5 nm to 1 μm.

A method of manufacturing a piezoelectric substrate for a SAW resonator according to an embodiment of the present invention may include a process of heat-treating the prepared laminated substrate 100. Referring to FIG. 3A or 3B, the heat treatment may be annealing (500) the laminated substrate 100 to which the support substrate 110, the low-sonic layer 120, and the piezoelectric layer 130 are bonded in a heat treatment chamber.

When the laminated substrate 100 is heated, in particular, argon (Ar) and oxygen (O2) contained in the low-sonic layer 120 may be outgasified, and thus the content thereof may be lowered. This will be described using FIG. 4.

FIGS. 4A to 4D are diagrams for explaining effects that may be obtained by the method of manufacturing a piezoelectric substrate for a SAW resonator according to an embodiment of the present invention.

Referring to FIG. 4A, as the laminated substrate 100 is heated, impurities contained in the laminated substrate 100 may be outgasified. Release of oxygen (O2) is confirmed at a heating temperature of about 200° C. to about 350° C., and release of argon (Ar) is confirmed at about 400° C. to about 600° C. This may also be confirmed by changes in argon components (FIG. 4B) and OH— (FIG. 4C) before and after the heat treatment shown in FIGS. 4B and 4C. Referring to FIG. 4b, it can be seen that the reduction of the argon component is confirmed from the decrease in the peak intensity of the argon component contained in the low-sonic layer (120). In FIG. 4C, it may be confirmed that the content of moisture (H2O) is reduced by heat treatment from a decrease in OH— at the interface of each layer.

Meanwhile, in FIG. 4d, from the stabilization of the SiO2 detection peak at the interface between the low-sonic layer (120) and the piezoelectric layer (130) or the high-sonic layer (140) before and after the heat treatment, it can be seen that the composition uniformity of SiO2 is improved by the heat treatment.

Crystallinity and internal defects of the low-sonic layer 120 and the high-sonic layer 140 may be improved by the emission of the gas. Also, bonding strength between the low-sonic layer 120 and the piezoelectric layer 130 may be improved by the heat treatment.

Meanwhile, cracks may occur in each layer during heat treatment due to different coefficients of thermal expansion of each layer forming the laminated substrate. For example, when the support substrate 110 is silicon and the low-sonic layer 120 is silicon oxide, the coefficients of thermal expansion thereof are about 3.4 and 0.6 (ppm/° C.), respectively. On the other hand, since the piezoelectric layer 130 of the LT/LN substrate is about 15 to 18 ppm/° C., the heated laminated substrate 100 may be destroyed.

In the method of manufacturing a piezoelectric substrate for a SAW resonator according to an embodiment of the present invention, since the piezoelectric layer 130 of 1 μm or less is used, the thermal stress is reduced, thereby reducing the possibility of cracking. In addition, considering that the Curie temperature of the LT substrate is about 600° C., the heat treatment of the laminated substrate 100 may be performed by increasing the temperature in the heat treatment chamber to 200° C. to 600° C.

FIGS. 5A to 5C are for describing effects according to a method of manufacturing a piezoelectric substrate for a SAW resonator according to an embodiment of the present invention.

Referring to FIG. 5A, an increase in the maximum Qmax value may be observed in the piezoelectric substrate heat-treated by heating up to 600 degrees compared to the conventional piezoelectric substrate Ref.

In addition, as shown in FIGS. 5B and 5C, when the duty ratio (DF) of the IDT electrode is set to 0.45, and the wavelength (Lambda) is changed according to the interval, an improvement of about 13 to 19% may be observed at the Qmax value. At this time, there was no change in the resonance frequency and the anti-resonance frequency.

As described above, a method of manufacturing a piezoelectric substrate for a SAW resonator according to an embodiment of the present invention and a piezoelectric substrate for a SAW resonator manufactured thereby show improved crystallinity and bonding strength by reducing impurities by outgassing under certain temperature conditions, and can have an improved Qmax value when manufactured with a SAW resonator.

FIG. 6 is a flowchart illustrating a method of manufacturing a piezoelectric substrate for a SAW resonator according to another embodiment of the present invention.

Referring to FIG. 6, a method of manufacturing a piezoelectric substrate for a SAW resonator according to another embodiment of the present invention includes preparing a laminated substrate (S210), reducing gas by heat-treating the laminated substrate (S220), and bonding the piezoelectric layer to the heat-treated low-sonic layer (S230). The manufacturing method according to the present embodiment is to prepare a laminated substrate 50 including a low-sonic layer 120 to which the piezoelectric layer 130 is not bonded and a support substrate 110, and to bond the piezoelectric layer 130 to the surface of the low-sonic layer 120 after the heat treatment of the laminated substrate 50 is completed. Hereinafter, the manufacturing method of the present invention will be described in more detail with reference to FIG. 7A and the like.

Referring to FIG. 7A, a laminated substrate 50 including the support substrate 110 and the low-sonic layer 120 may be prepared, and impurities contained in the laminated substrate 50 may be removed by annealing (500) the laminated substrate 50 in the chamber. In some embodiments, as illustrated in FIG. 7B, a high-sonic layer 140 may be additionally formed between the support substrate 110 and the low-sonic layer 120 of the laminated substrate 50.

Oxygen (O2) can be released from the low-sonic layer (120) at 200° C. to 350° C. during the heat treatment of the laminated substrate (50), and argon (Ar) can be released at 400° C. to 600° C.

Next, referring to FIGS. 8A and 8B, the piezoelectric layer 130 may be bonded to the surface of the heat-treated laminated substrate 51, in particular, to the surface of the low-sonic layer 120. The piezoelectric layer 130 may be bonded to one surface of the low-sonic layer 120 by a bonding surface formed by polishing one surface of a single crystal LT or LN substrate, and in some cases, a process in which the piezoelectric layer 130 is thinned after bonding may be added.

FIG. 9 is a flowchart illustrating a method of manufacturing a piezoelectric substrate for a SAW resonator according to another embodiment of the present invention.

Referring to FIG. 9, a method of manufacturing a piezoelectric substrate for a SAW resonator according to another embodiment of the present invention includes preparing a laminated substrate (S310), reducing gas by heat-treating the laminated substrate (S320), and bonding a support substrate to a heat-treated low-sonic layer (S330). The difference between this manufacturing method and the previous one is to prepare a laminated substrate (52) that includes a low-sonic layer (120) and a piezoelectric layer (130) but is not bonded to the support substrate (110) and to bond the support substrate (110) to the surface of the low-sonic layer (120) after the heat treatment of the laminated substrate (52) is completed.

Hereinafter, the manufacturing method of the present invention will be described in more detail with reference to FIG. 10, etc.

FIGS. 10 to 11b are intermediate step diagrams of a method of manufacturing a piezoelectric substrate for a SAW resonator according to another embodiment of the present invention.

Referring to FIG. 10, it is illustrated that a laminated substrate 52 in which a piezoelectric layer 130 is bonded to the low-sonic layer 120 is prepared, and an annealing (500) of the laminated substrate 52 is performed.

As the laminated substrate 52 is heated, oxygen (O2) may be released from the low-sonic layer 120 at about 200° C. to 350° C., and argon (Ar) may be released at about 400° C. to 600° C. Although there is a significant difference between the thermal expansion coefficient of the low-sonic layer 120 including silicon oxide and the thermal expansion coefficient of the piezoelectric layer 130, the possibility of cracking may be reduced by minimizing the thermal stress applied to the low-sonic layer 120 by the piezoelectric layer 130 having a small thickness of 1 μm or less.

Subsequently, referring to FIGS. 11A and 11B, the support substrate 110 or the high-sonic layer 140 bonded to the support substrate 110 may be bonded to the surface of the heat-treated laminated substrate 53 (i.e., the surface of the low-sonic layer 120). Such bonding may be performed through plasma activation bonding or hydrophilic bonding.

FIGS. 12 and 13 are intermediate step diagrams of a method of manufacturing a piezoelectric substrate for a SAW resonator according to another embodiment of the present invention.

Referring to FIG. 12, it is illustrated that a laminated substrate 54 in which a piezoelectric layer 130 and a high-sonic layer 140 are bonded to the upper and lower portions of the low-sonic layer 120 is prepared, and the laminated substrate 54 is annealed (500) to perform outgassing.

As the laminated substrate 54 is heated, oxygen (O2) may be released from the low-sonic layer 120 at about 200° C. to 350° C., and argon (Ar) may be released at about 400° C. to 600° C.

Although there is a significant difference between the thermal expansion coefficient of the low-sonic layer 120 including silicon oxide and the thermal expansion coefficient of the piezoelectric layer 130, the thermal stress applied to the low-sonic layer 120 is minimized due to the piezoelectric layer 130 having a small thickness of less than 1 μm, thereby reducing the possibility of cracking.

Subsequently, referring to FIG. 13, the support substrate 110 may be bonded to the surface of the heat-treated laminated substrate 54 (i.e., the surface of the high-sonic layer 140. Such bonding may be performed through plasma activation bonding or hydrophilic bonding.

Although the present invention has been described as described above, those skilled in the art will recognize that the present invention may be implemented in other forms while maintaining the technical ideas and essential features of the present invention.

Although the scope of right of the present invention will be determined basically by the patent claims, it should be interpreted that all changes or modified forms derived from equivalent configurations, as well as the configurations directly derived from the description of the patent claims, are included in the scope of right of the present invention.

What is claimed is:

1. A method of manufacturing a piezoelectric substrate for a surface acoustic wave (SAW) resonator comprising:
Preparing a laminated substrate; and
Heat-treating the laminated substrate to reduce the gas contained in at least one layer of the laminated substrate.

2. The method of claim 1, wherein the laminated substrate contains a low-sonic layer.

3. The method of claim 2, wherein the laminated substrate further contains a support substrate formed on one side of the low-sonic layer.

4. The method of claim 3, wherein the laminated substrate further contains a high-sonic layer formed between the support substrate and the low-sonic layer.

5. The method of claim 3, further comprising:
Bonding the piezoelectric layer to the upper surface of the low-sonic layer.

6. The method of claim 2, wherein the laminated substrate further contains a piezoelectric layer formed on one surface of the low-sonic layer.

7. The method of claim 6, wherein the thickness of the piezoelectric layer is 200 nm to 2 μm.

8. The method of claim 6, further comprising:
Bonding the heat-treated laminated substrate and the support substrate.

9. The method of claim 8, wherein, bonding the heat-treated laminated substrate and the support substrate includes bonding other surface of the low-sonic layer and one surface of the high-sonic layer formed on one surface of the support substrate.

10. The method of claim 6, wherein the laminated substrate further contains a silicon support substrate formed on the other surface of the low-sonic layer.

11. The method of claim 1, wherein, heat-treating the laminated substrate to reduce the gas contained in at least one layer of the laminated substrate includes heat-treating the laminated substrate under temperature condition of 400 to 600° C.

12. The method of claim 11, wherein, heat-treating the laminated substrate to reduce the gas contained in at least one layer of the laminated substrate further includes heat-treating the laminated substrate under temperature condition of 200 to 350° C.

13. The method of claim 1, wherein, the gas to be reduced by heat-treating is at least one of H2, H2O, O2, and Ar.

14. The method of claim 12, wherein, heat-treating the laminated substrate to reduce the gas contained in at least one layer of the laminated substrate includes performing heat treatment while increasing the temperature in the heat treatment chamber from 200° C. to 600° C.

15. A piezoelectric substrate for SAW resonators manufactured by the method of claim 1.
